(19) United States
(12) Patent Application Publication
(10) Pub. No.: US 2015/0092192 A1
(43) Pub. Date: Apr. 2, 2015

(54) Lighting device comprising measuring device and method for operating the lighting device

(71) Applicant: OSRAM GmbH, Muenchen (DE)

(72) Inventors: Georg FORSTER, Regensburg (DE); Stefan HADRATH, Falkensee (DE)

(21) Appl. No.: 14/495,968

(22) Filed: Sep. 25, 2014

(30) Foreign Application Priority Data
Oct. 1, 2013 (DE) 102013219930.9

(51) Int. Cl. G01J 3/50; H01S 5/06; H05B 37/02; H05B 33/08; G01J 3/46; G01J 3/02

(52) U.S. Cl. CPC G01J 3/505; G01J 3/462; G01J 3/0205; H05B 37/0218; H05B 33/0869; H01S 5/06
USPC 356/402; 315/153; 359/629

(57) ABSTRACT

Various embodiments may relate to a lighting device including at least two light sources, the light from which has different spectra and is combined to form useful light. For measuring the portions of the light from the individual light sources, part of the useful light, the measurement light, is branched off with the aid of a coupling-out element at the output of the lighting device and is fed to a measuring device.

### CROSS-REFERENCE TO RELATED APPLICATION

This application claims priority to German Patent Application Serial No. 10 2013 219 930.9, which was filed Oct. 1, 2013, and is incorporated herein by reference in its entirety.

### TECHNICAL FIELD

Various embodiments generally relate to a lighting device including at least one first light source and one second light source, wherein both light sources emit light having different spectra. Furthermore, various embodiments generally relate to a method for operating this lighting device.

The disclosure is applicable, in particular, to projection devices, for example for film and video projection, in technical and medical endoscopy, for lighting effects in the entertainment industry, for medical irradiations and in the automotive sector, in particular as a headlight for motor vehicles.

### BACKGROUND

The document WO2012/116733 discloses a lighting device of the generic type. It includes a blue light source and a yellow light source, which are combined by means of a dichroic mirror and mixed to form white light. The blue light source is embodied as a blue light emitting diode (LED), and the yellow light source as a so-called LARP system, wherein laser radiation is wavelength-converted into yellow light by means of yellow phosphor (LARP: “Laser Activated Remote Phosphor”). In order to control the corresponding color temperature (CCT) of the white mixed light or generally the color locus of the mixed light, the light from the blue LED and from the yellow phosphor that is scattered at optical units is measured by means of a respective measuring element. The two measurement signals are used for driving the laser or the LED.

What is disadvantageous about this method is that the scattered radiation can vary over the lifetime of the lighting device, such that the initial correlation between the measurement signals and the output luminous flux no longer exists. A correct mixing of the two light portions is then no longer possible.

Moreover, back-reflections from the output of the lighting device can disturb the measurements. FIG. 3 shows a corresponding lighting device 100 including photodiodes 101, 102 arranged respectively in proximity to an LED 12 and a phosphor layer 9. The mixed light is usually homogenized in an optical integrator 17 and subsequently coupled into an optical fiber 24, for example. Back-reflections 23 of the useful light 15b that occur at the input to the optical fiber 24 in this case can impinge on the photodiode 101 assigned to the LED 12, for example, as is shown by way of example for one light ray in FIG. 3. For further details concerning the construction of the lighting device, reference is made to the description of FIG. 1.

### SUMMARY

Various embodiments provide a lighting device including an improved lighting measuring device.

A further aspect is to utilize the lighting measuring device for regulating lighting variables of the useful light of the lighting device.

Various embodiments provide a lighting device, including at least one first light source and one second light source, wherein the first light source is designed to emit light having a first spectrum, and wherein the second light source is designed to emit light having a second spectrum, an optical device for combining the light having the first spectrum with the light having the second spectrum onto a common useful light path to form useful light, an optical coupling-out element, which is arranged in the common useful light path and is designed for coupling out part of the useful light from the common useful light path onto a measurement light path for use as measurement light, a measuring device, which is arranged in the measurement light path and is designed for measuring the measurement light.

Hereinafter, features that relate more to the aspects of the disclosure appertaining to the device subject matter are also explained jointly together with features that characterize rather the technical aspects appertaining to the method, in order to facilitate an understanding of the technical relationships of the disclosure.

The basic concept of the present disclosure consists in performing, in the case of a lighting device including at least two light sources, the measurement of lighting variables of the useful light at the output, i.e. with part of the useful light itself. This part of the useful light, the measurement light, is branched off from the useful light with the aid of a coupling-out element at the output of the lighting device.

Since the measurement of the lighting variables therefore takes place at the output of the lighting device with part of the useful light, and not with the scattered light from the individual light sources to be mixed, it is less susceptible to lifetime- or temperature-dictated changes in the optical components of the lighting device.

The coupling-out element may include, for example, a glass plate or a mirror and reflects the measurement light portion from the useful light onto the measuring device. With the use of a mirror, the latter may be chosen to be small in comparison with the diameter of the useful light beam, in order to attenuate the useful light only by a measurement light portion indispensible for the measurement.

The measuring device may include at least one measuring element. The at least one measuring element is designed to measure both the light having the first spectrum that comes from the first light source and the light having the second spectrum. For this purpose, the measuring element is designed, for example, as a combined colored light sensor. Alternatively, individual photodiodes in each case with a corresponding color filter may also be provided.

In various embodiments, the measuring device may includes an optical mixing chamber for the measurement light, the at least one measuring element being arranged in said chamber. Preferably, the inner surface of the optical mixing chamber is configured in a diffusely reflective fashion in the manner of an Ulbricht sphere.

By means of a suitable design, in particular alignment of the coupling-out optical unit and form of the mixing chamber, it is possible to reduce the influence of back-reflections from the output on the measurement. For further details in this respect, reference is made to the exemplary embodiments.

For combining the light from the first light source and the light from the second light source onto the common useful light path, the optical device may includes, for example, a dichroic mirror designed to reflect the light from one light source and to transmit the light from the other light source.

Appropriate light sources for the lighting device include, in particular, semiconductor light sources, for example light emitting diodes or laser diodes. Furthermore, at least one of the light sources may additionally include at least one phosphor designed to convert the primary light from at least one light emitting diode or laser diode into secondary light having a longer wavelength. By adapting the respective operating currents of the individual light sources, for example by means of amplitude or pulse width modulation (PWM), it is possible to set the spectral composition of the mixed light (useful light).

In various embodiments, the lighting device may include a control device, which is connected to the measuring device, on the one hand, and to the first light source and the second light source, on the other hand. As a result, it is possible to use the measurement values of the measuring device for determining suitable setpoint values for the controlled variables for the individual light sources. In one development, the control device may include a color management system designed to calculate, from predefined lighting setpoint values for the combined useful light, the requisite setpoint values for the luminous fluxes of the individual light sources and therefrom the requisite setpoint values for the controlled variables of the individual light sources.

A method for operating a lighting device including the technical features mentioned above may include, in particular, the following method steps:
A) The first step involves calculating the necessary portions of a lighting variable, e.g. the luminous flux, of the individual sources in order to attain the necessary target luminous flux and target color locus of the useful light of the lighting device.
B) The color management system of the control device calculates the controlled variables in order to obtain the lighting variables ascertained in step A) at the output of the lighting device.
C) A driver unit converts the communicated controlled variables into the manipulated variable of a regulating unit. Manipulated variables are the electric currents through the laser diodes and/or LEDs. The current may be amplitude-modulated (variable current intensity) and/or PWM-modulated.
D) The respective light source may be measured e.g. by means of the following sensors:
   V(λ)-weighted brightness sensor and temperature sensor,
   brightness sensor and temperature sensor,
   color sensor.

These sensors are used to detect, by means of the light source characterization (characteristic curves and calibration of the light sources), the present luminous flux of the individual light sources (colored light portions) and also the variation of the individual color locus (Cx, Cy) and/or the variation of the color locus at the output of the lighting device.
E) The color management system then calculates the luminous fluxes of the individual light sources that are to be newly set, and thus reacts to the occurrence of changes (e.g. decrease in luminous flux over lifetime and/or color locus shifts) and stabilizes the total luminous flux and/or color locus. The necessary luminous flux changes are converted into the new manipulated variable. The regulating control loop is thus closed.

In the case of a lighting device including two light sources, in particular semiconductor light sources including LARP light sources, the proposed method affords the advantage that a freely predefinable output luminous flux (or some other lighting variable) may be kept constant by means of regulation. The influencing variables to be regulated may be temperature, current and/or aging.

In addition, it is possible to take account of predictable changes in the color locus of the LARP and/or LED sources by means of feed forward regulation (characteristic curves). The target color locus may be tracked along an e.g. Judd straight line or some other defined line which has a point of intersection with the connecting straight line of a lighting device including two different light sources.

In the case of a lighting device including three different light sources, in addition to the above, the target color locus may be exactly and unambiguously readjusted.

In the case of a lighting device including more than three light sources, the additional degree of freedom may be used to optimize an additional variable. Such an additional target variable may be e.g. the color rendering index (CRI) or some other application-dependent spectral distribution.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows one exemplary embodiment of a lighting device including a measuring element that is arranged on the output side and is irradiated directly,

FIG. 2 shows one exemplary embodiment including a measuring element arranged on the output side within a mixing chamber,

FIG. 3 shows one exemplary embodiment including a measuring element arranged in accordance with the prior art,

FIG. 4 shows a regulating arrangement with color management system, and

FIG. 5 shows a flowchart of the regulation in accordance with FIG. 4 in the case of a lighting device in accordance with the exemplary embodiment according to FIG. 1 or FIG. 2.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

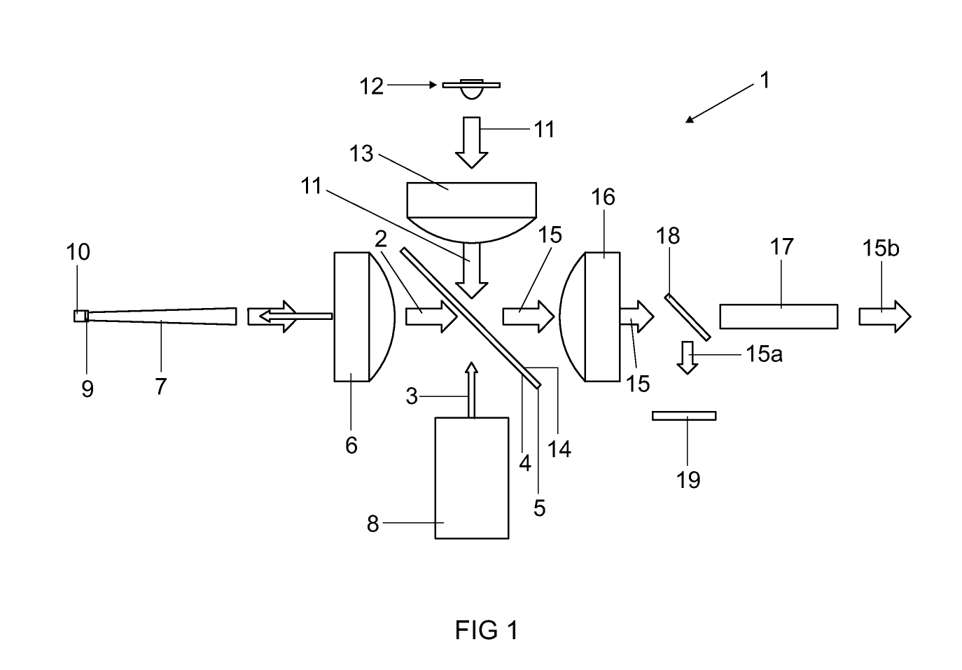

FIG. 1 shows a schematic illustration of a lighting device 1 for generating white mixed light made from yellow and blue light.

The lighting device 1 illustrated is suitable for example as a replacement for a xenon discharge lamp in lighting arrangements such as endoscopy, microscopy or medical head lamps.

The yellow light (symbolized by the arrow 2) is generated by means of LARP technology. For this purpose, laser radiation (symbolized by the arrow 3) is reflected from the front side 4 (as viewed from left to right in FIG. 1) of a dichroic mirror 5 onto a lens 6, which focuses the laser radiation 3 onto the entrance surface of an elongate TIR optical unit 7. The laser radiation 3 is emitted by a laser device 8 including e.g. a laser diode matrix composed of a plurality of, for example six times seven, blue laser diodes (not illustrated). The TIR optical unit 7 guides the laser radiation by total internal reflection (TIR) onto a yellow phosphor layer 9 arranged at its end. The elongate TIR optical unit 7 is shaped conically, its narrower end facing the yellow phosphor layer 9. The yellow phosphor layer 9 is arranged on a heat sink 10.

The front side 4 of the dichroic mirror 5 is provided with an interference coating that reflects blue light and transmits other colored light portions, in particular the yellow light 2 wavelength-converted by the yellow phosphor layer 9.

The blue light (symbolized by the arrow 11) is admixed from one or a plurality of blue LEDs 12 (e.g. LE B Q6WP from OSRAM Opto Semiconductor). For this purpose, the blue LED light 11 is directed onto the rear side 14 of the dichroic mirror 5 via a collimation lens 13. The rear side 14 is provided with an interference coating that reflects the blue LED light 11 and transmits the yellow light 2. Given suitable alignment of all the optical components, a white mixed light 15 results. The white mixed light 15 is focused into a light mixer 17 via a third lens 16. The light mixer 17 is embodied for example as a glass rod or waveguide, e.g. mirror tunnel, and serves for homogenizing the mixed light.

Arranged between the third lens 16 and the light mixer 17 there is a glass plate 18 (alternatively a small mirror; not illustrated), the front side (as viewed from left to right in FIG. 1) of which couples out part 15a of the mixed light 15 onto a measuring element 19 by reflection.

The measuring element 19 has two photodiodes (alternatively a combined element) and serves for measuring the two colored light portions of the measurement light 15a branched off from the mixed light 16. For this purpose, one photodiode is provided with a yellow filter, and the other with a blue filter (not illustrated). In a further alternative (not illustrated), a single photodiode without a filter can also be used as measuring element 19 and the measurement signals for the two colored light portions 2, 11 of the measurement light 15a can thus be determined sequentially. For this purpose, the laser device 8 and the LEDs 12 are operated in an alternately clocked fashion with the aid of associated clock signals and the measurement signals are assigned in a manner corresponding to the respective clock signal. This procedure has the advantage that there is no crosstalk of one colored light portion to the measurement of the other colored light portion. Moreover, the measurement of both colored light portions takes place exactly at the same location. Finally, no optical filters are required. Problems associated therewith, for example with regard to filter lifetime or stray light at the filter edges, are avoided.

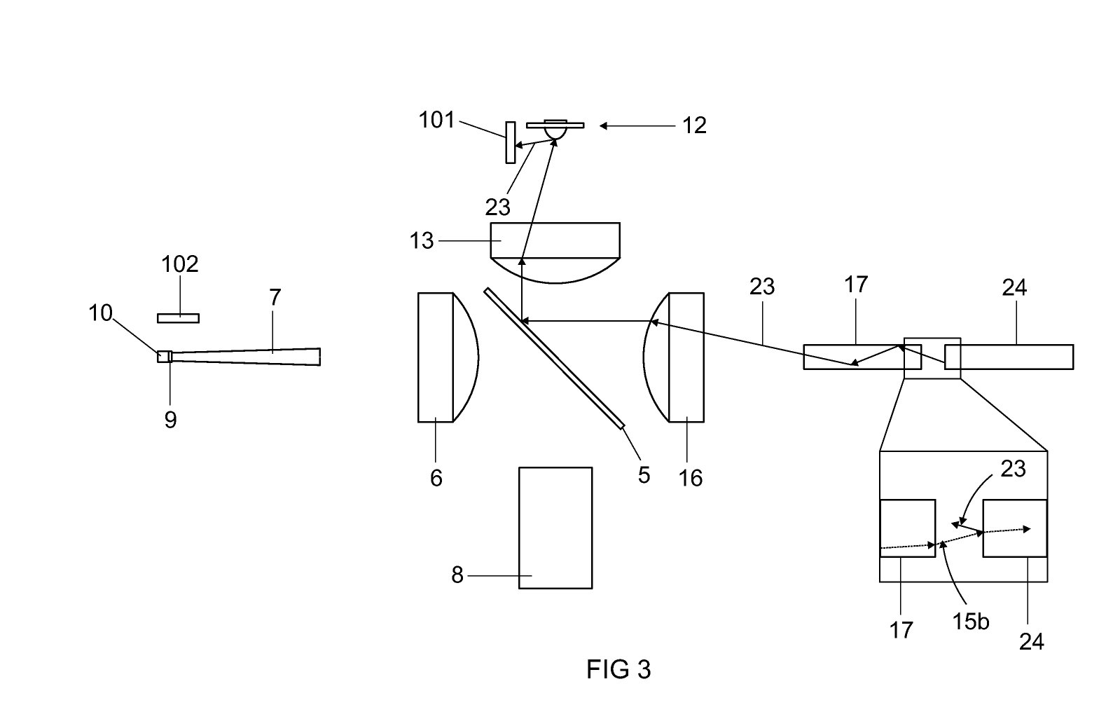

The remaining portion of the mixed light is available as useful light 15b for further use, for example for coupling into an optical fiber (not shown in FIG. 1). On account of the measurement of the colored light portions at the output of the lighting device 1 in accordance with FIG. 1, the measurement result is influenced by lifetime changes to a lesser extent than in the case of the direct measurement of the scattered radiation from the LED 12 and the phosphor layer 9 in accordance with FIG. 3. Moreover, back-reflections from the output of the lighting device can disturb the measurements to a lesser extent.

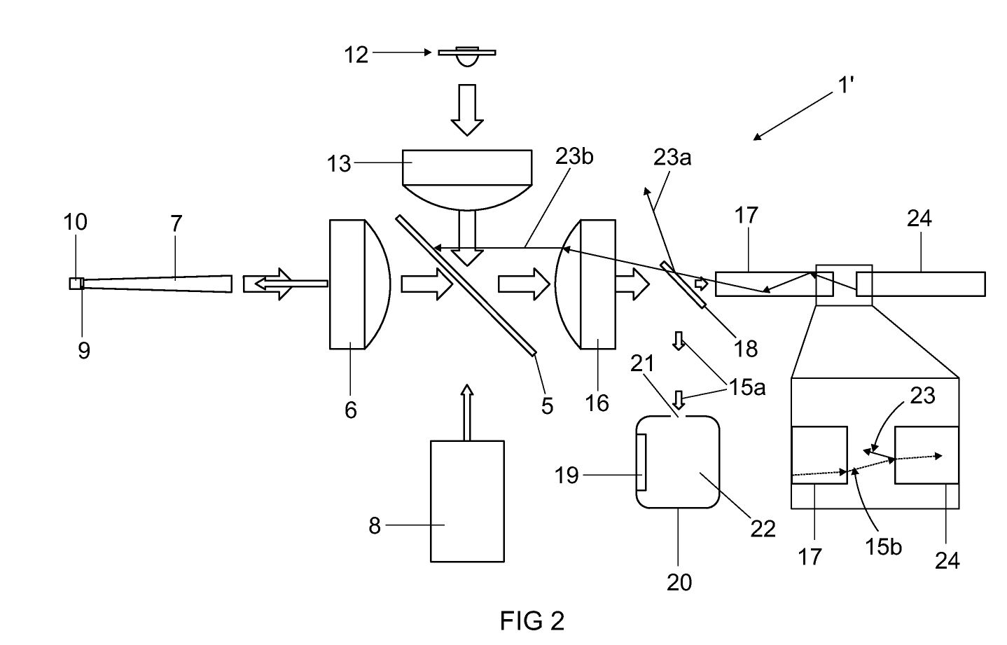

In connection with back-reflections such as occur, for example, when the useful light 15b is coupled into an optical fiber, reference is made below to FIG. 2, which illustrates a variant 1′ of the lighting device shown in FIG. 1. The sole difference is that the measuring element 19 is arranged in a measuring chamber 20. The measuring chamber 20 is embodied as a cavity having diffusely reflective inner walls in the manner of an Ulbricht sphere. In this case, the measurement light 15a is directed through a hole 21 into the interior 22 of the measuring chamber 20. A possible back-reflection 23 of the useful light 15b at the input of an optical fiber 24 disposed downstream of the light mixer 17, said back-reflection passing back into the light mixer 17, is reflected away from the measuring chamber 20 in part 23a by the rear side of the glass plate 18, that is to say cannot disturb the measurement. The part 23b transmitted by the glass plate 18 likewise propagates past the measuring chamber 20 and therefore, in contrast to the arrangement shown in FIG. 3, cannot impinge on the measuring element 19.

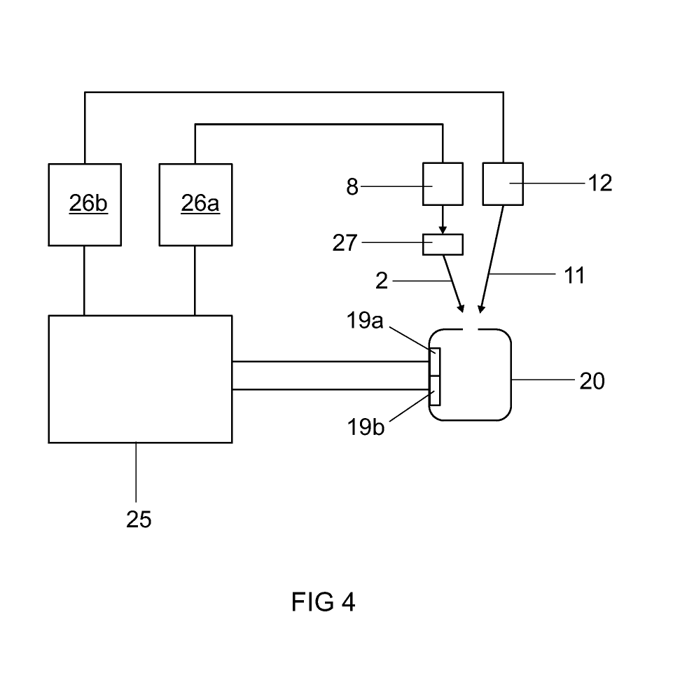

For regulating the total luminous flux Φ and the CCT of the useful light 15b, the lighting device 1 illustrated schematically in FIG. 1 or the lighting device 1′ illustrated schematically in FIG. 2 is additionally equipped with a color management system. Hereinafter, reference is also made to FIG. 4, which shows the regulating arrangement in a roughly schematic manner. The measurement signals of the two measuring elements 19a, 19b (photosensor with yellow filter and blue filter, respectively) arranged within the measuring chamber 20 for the yellow light 2 and blue light 11, respectively, are fed to a color management system 25. From these measurement values, the color management system 25 calculates the correction values necessary, if appropriate, for the yellow and blue partial luminous fluxes Φ_{LARP} and Φ_{LED}, respectively, and the corresponding controlled variables for the laser 8 and the LED 12. Laser 8 and LED 12 are correspondingly driven via associated drivers 26a, 26b. The measurement light portion of the light from the laser 8 that is wavelength-converted into yellow light 2 by means of phosphor conversion 27 and the measurement light portion of the blue light 11 from the LED 12 are coupled into the measuring chamber 20 via the coupling-out element (not illustrated here for the sake of better clarity). The regulating control loop is thus closed.

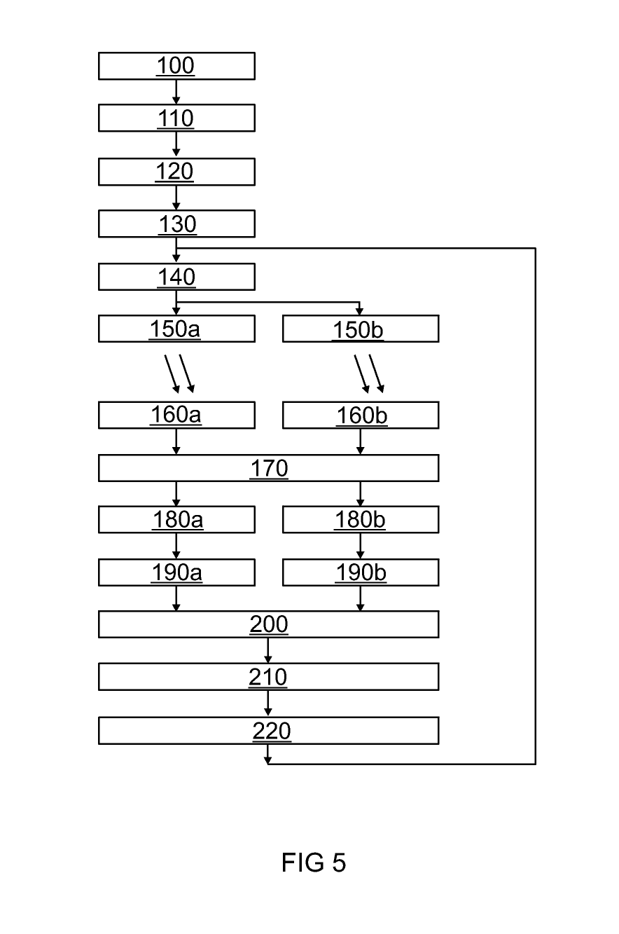

FIG. 5 illustrates a flowchart for the regulation outlined schematically in FIG. 4 in the case of a lighting device in accordance with the exemplary embodiment according to FIG. 1 or FIG. 2. Therefore, hereinafter, reference is also made to FIGS. 1, 2 and 4 in addition to FIG. 5. The first step 100 involves predefining the setpoint values for the lighting variables of the white mixed light 15, in particular the total light intensity Φₛₑₜₚₒᵢₙₜ, the correlated color temperature CCT_{setpoint,} and optionally a dimming level D%. The subsequent step 110 involves calculating the requisite proportional luminous fluxes Φ_{LARP} and Φ_{LEA} for the yellow light 2 and the blue light 11, respectively, and step 120 involves calculating therefrom the required digital setpoint current values DAC_{LD} and DAC_{LED} for the laser diodes 8 of the LARP yellow light source and the blue LED 12, respectively. This calculation is carried out in the color management system 25 in accordance with FIG. 4 in the present case. The digital setpoint current values DAC_{LD} and DAC_{LED} are set in step 130 and, in step 140, are converted into associated current values I_{LD} and I_{LED}, respectively, in each case in a digital-to-analog converter (DAC) of the two drivers 26a, 26b and are output. Steps 150a, 150b involve driving the laser diodes 8 of the LARP yellow light source and the blue LED 12 with the current values I_{LD} and I_{LED}, respectively, whereupon the former emit the yellow luminous flux Φ_{LARP} via the phosphor conversion 27 and the latter emit the blue luminous flux I_{LED} directly. Steps 160a, 160b involve measuring the luminous fluxes respectively by means of an optical measuring element 19a for the yellow LARP light 2 and an optical measuring element 19b for the blue LED light 11. Moreover, the temperature of the measuring elements 19a, 19b is in each case measured by means of associated NTC measuring elements (not illustrated). These analog measurement values are in each case converted into corresponding digital values with the aid of ADC converters in step 170. In steps 180a, 180b, the digitized measurement values ADC_Φ_{LARP} and ADC_Φ_{LED} are temperature-compensated with the aid of the temperature measurement values NTC_measuring element_LARP and NTC_measuring element_LED, respectively. In steps 190a, 190b, the actual respective luminous fluxes Φ_{LARP}_{_{—}}_{actual} and Φ_{LED}_{_{—}}_{actual} are calculated from these temperature-compensated values with the aid of associated calibration coefficients. In step 200, the regulating deviations ΔΦ_{LARP} and ΔΦ_{LED} are calculated from the difference between the actual values Φ_{LARP}_{_{—}}_{actual}, Φ_{LED}_{_{—}}_{actual} and the associated setpoint values Φ_{LARD} and Φ_{LED} from step 110. The regulating deviations for the respective luminous fluxes are converted into DAC deviations ΔDAC_{LD} and ΔDAC_{LED} in step 210 and finally into the new DAC manipulated variables DAC_{LD} and DAC_{LED} for the drivers 26a, 26b in step 220, i.e. the sequence jumps back to step 140 and the regulating control loop is closed.

The disclosure proposes a lighting device including at least two light sources, the light from which has different spectra and is combined to form useful light. For measuring the portions of the light from the individual light sources, part of the useful light, the measurement light, is branched off with the aid of a coupling-out element at the output of the lighting device and is fed to a measuring device.

1. A lighting device, comprising:
at least one first light source and one second light source, wherein the first light source is designed to emit light having a first spectrum, and wherein the second light source is designed to emit light having a second spectrum, an optical device for combining the light having the first spectrum with the light having the second spectrum onto a common useful light path to form useful light,
an optical coupling-out element, which is arranged in the common useful light path and is designed for coupling out part of the useful light from the common useful light path onto a measurement light path for use as measurement light, and
a measuring device, which is arranged in the measurement light path and is designed for measuring the measurement light.

2. The lighting device as claimed in claim 1, wherein the measuring device is designed for measuring light having the first spectrum and light having the second spectrum and comprises at least one measuring element.

3. The lighting device as claimed in claim 2, wherein the measuring device comprises an optical mixing chamber for the measurement light, the at least one measuring element being arranged in said chamber.

4. The lighting device as claimed in claim 3, wherein the inner surface of the optical mixing chamber is configured in a diffusely reflective fashion in the manner of an Ulbricht sphere.

5. The lighting device as claimed in claim 1, wherein the coupling-out element comprises a glass plate or a mirror and reflects the measurement light portion from the useful light onto the measuring device.

6. The lighting device as claimed in claim 1, wherein the optical device comprises a dichroic mirror designed to reflect the light from one light source onto the common useful light path and to transmit the light from the other light source onto the common useful light path.

7. The lighting device as claimed in claim 1, wherein at least one of the light sources comprises at least one light emitting diode or laser diode.

8. The lighting device as claimed in claim 7, wherein at least one of the light sources additionally comprises at least one phosphor designed to wavelength-convert the primary light from at least one light emitting diode or laser diode into secondary light.

9. The lighting device as claimed in claim 1, further comprising a control device, which is connected to the measuring device, on the one hand, and to the first light source and the second light source, on the other hand.

10. The lighting device as claimed in claim 9, wherein the control device comprises a color management system designed to calculate, from predefined lighting setpoint values for the combined useful light, the requisite setpoint values for the luminous fluxes of the individual light sources and therefrom the requisite setpoint values for the controlled variables of the individual light sources.

11. A method for operating a lighting device,
the lighting device comprising:
at least one first light source and one second light source, wherein the first light source is designed to emit light having a first spectrum, and wherein the second light source is designed to emit light having a second spectrum, an optical device for combining the light having the first spectrum with the light having the second spectrum onto a common useful light path to form useful light,
an optical coupling-out element, which is arranged in the common useful light path and is designed for coupling out part of the useful light from the common useful light path onto a measurement light path for use as measurement light,
a measuring device, which is arranged in the measurement light path and is designed for measuring the measurement light, and
a control device, which is connected to the measuring device, on the one hand, and to the first light source and the second light source, on the other hand,
wherein the control device comprises a color management system designed to calculate, from predefined lighting setpoint values for the combined useful light, the requisite setpoint values for the luminous fluxes of the individual light sources and therefrom the requisite setpoint values for the controlled variables of the individual light sources,
the method comprising:
in an initialization or change phase:
predefining lighting setpoint values for the combined useful light, determining the proportional luminous fluxes of the individual light sources for attaining the lighting setpoint values predefined in said predefining lighting setpoint values with the aid of the color management system of the control device, and
determining the controlled variables for the individual light sources for attaining the proportional luminous fluxes calculated in said determining the proportional luminous fluxes,
in a regulating phase:
outputting the controlled variables by means of the control device to the individual light sources,
measuring the lighting values of the measurement light coupled out with the aid of the optical coupling-out element with the aid of the measuring device,
determining the lighting actual values of the combined useful light from the measurement values of the measurement light obtained in said measuring the lighting values with the aid of the color management system, and
determining new controlled variables for the individual light sources if the lighting actual values of the combined useful light determined in said determining the lighting actual values deviate from their setpoint values predefined in said predefining lighting setpoint values, otherwise maintaining the previous controlled variables.

12. The method as claimed in claim 11, wherein the individual light sources are operated alternately in a clocked fashion with the aid of associated clock signals and the measurement values for the portions of the light from the respective light source are assigned and determined with the aid of a single measuring element in a manner corresponding to the respective clock signal.
